(19) United States
(12) Patent Application Publication
(10) Pub. No.: US 2022/0051157 A1
(43) Pub. Date: Feb. 17, 2022

(54) GROUND TRANSPORTATION MANAGEMENT USING SIMULATION AND MODELING

(71) Applicant: Lacuna Technologies, Inc., Palo Alto, CA (US)

(72) Inventors: Wesley Smith, Palo Alto, CA (US); Levi Crain, Palo Alto, CA (US); Max Johansen, Palo Alto, CA (US); Brian Ng, Palo Alto, CA (US)

(21) Appl. No.: 17/403,855

(22) Filed: Aug. 16, 2021

Related U.S. Application Data
(60) Provisional application No. 63/066,229, filed on Aug. 15, 2020.

(51) Int. Cl. G06Q 10/06; G06F 30/27; G06Q 30/02; G08G 1/09

(52) U.S. Cl. CPC G06Q 10/06315; G08G 1/09; G06Q 30/0205; G06F 30/27

(57) ABSTRACT

Systems and methods are described which manage, in real time, and without impeding the natural flow of vehicles, a preferred flow of traffic within a geographic location based on prior modeling and simulation.

This Patent application claims priority to U.S. Provisional Patent Application Ser. No. 63/066,229, filed Aug. 15, 2020; the content of which is hereby incorporated by reference herein in its entirety into this disclosure.

### BACKGROUND OF THE SUBJECT DISCLOSURE

### Field of the Subject Disclosure

The present subject disclosure relates to transportation management. More specifically, the present subject disclosure relates to ground transportation management using simulation and modeling.

### Background of the Subject Disclosure

The ever-growing population of humans in urban areas has resulted in increased congestion and gridlock. Certain venues in particular, such as transportation hubs, are almost always associated with heavy traffic. In many such transportation hubs, thousands of passengers arrive and depart daily. The associated heavy traffic slows down ground transportation and results in further stress particularly for travelers who are trying to catch their flight.

As a busy transportation hub, such as an airport, faces increased traffic, the flow through slows down considerably at a time when increased numbers of passengers or commercial vehicles need to enter or leave the hub, resulting in even further delays, thereby exacerbating the bottleneck and increasing the stress on the people, vehicles, and physical grounds of the hub.

Traffic officers may be used to direct traffic and prevent drivers from spending too much time idling at the curb of a gate. However, traffic still persists and gridlock is the norm at virtually every major airport in the world.

### SUMMARY OF THE SUBJECT DISCLOSURE

The present subject disclosure provides a technological solution to the technological problem of determining and implementing efficient traffic flow through a congested area by determining the types of vehicles within that area, and which roads or traffic patterns will result in idealized and efficient flow through outcomes. Normal traffic flow must be maintained in order to prevent bottlenecks and congestion at airport terminals and staging or auxiliary lots. The present subject disclosure describes systems and methods to address issue of commercial use of a property by multi-purpose or commercial vehicles, to thereby allow efficient flow through the property while also rightfully compensating the facility, for the use. In the description and drawings presented herein, an airport is used for sake of simplicity. However, the present systems and methods are not limited to airports, but may be any private, commercial, or government property or facility which may benefit from the use of traffic pattern simulation and management, as appreciated by one having ordinary skill in the art.

In one exemplary embodiment, the present subject disclosure is a system for managing ground transportation. The system includes a logic component on a server system which receives traffic information about a plurality of vehicles within a geographically defined area; a logic component on a server system that provides the traffic information to a machine learning engine, wherein the machine learning engine contains a plurality of traffic pattern simulations; a logic component on the server system that provides a prediction of the traffic pattern simulation based on the traffic information; and a logic component on the server system that redirects traffic in response to the prediction based on the traffic information.

In another exemplary embodiment, the present subject disclosure is a system for managing ground transportation. The system includes a logic component on a server system which receives traffic information about a plurality of commercial vehicles within a geographically defined area; a logic component on a server system that provides the traffic information to a machine learning engine, wherein the machine learning engine contains a plurality of traffic pattern simulations; a logic component on the server system that provides a prediction of the traffic pattern simulation based on the traffic information; and a logic component on the server system that redirects traffic in response to the prediction based on the traffic information; wherein the traffic information and the prediction are stored into the machine learning engine to be used for future predictions.

In yet another exemplary embodiment, the present subject disclosure is a method of managing ground transportation. The method includes a receiving traffic information about a plurality of commercial vehicles within a geographically defined area; providing the traffic information to a machine learning engine, wherein the machine learning engine contains a plurality of traffic pattern simulations; providing a prediction of the traffic pattern simulation based on the traffic information; and redirecting traffic in response to the prediction based on the traffic information.

### BRIEF DESCRIPTION OF THE DRAWINGS

FIG. 1 shows an airport management system screen, according to an exemplary embodiment of the present subject disclosure.

FIG. 2 shows a flow chart of simulated data sets being uploaded into a Machine Learning (ML) engine, according to an exemplary embodiment of the present subject disclosure.

FIG. 3 shows a flow chart of real world conditions being tested within a Machine Learning (ML) engine to predict various outcomes for a decisionmaker, according to an exemplary embodiment of the present subject disclosure.

FIG. 4 shows testing platform systems using a streaming technique, according to an exemplary embodiment of the present subject disclosure.

FIG. 5 shows testing platform systems using static files, according to an exemplary embodiment of the present subject disclosure.

FIG. 6 shows a simulator architecture, according to an exemplary embodiment of the present subject disclosure.

FIG. 7 shows a flow chart of how a simulator may operate, according to an exemplary embodiment of the present subject disclosure.

FIG. 8 shows a simulator control of an airport, according to an exemplary embodiment of the present subject disclosure.

FIG. 9 shows an interaction with a commercial operator, according to an exemplary embodiment of the present subject disclosure.

### DETAILED DESCRIPTION OF THE SUBJECT DISCLOSURE

The present subject disclosure provides a technological solution to the technological problem of directing vehicles, in real time, and without impeding the natural flow, through a congested area in a manner which accelerates the throughput of vehicles in that area, and/or for optimizing vehicles in staging lots in an airport in view of how many trips are expected.

The present subject disclosure features traffic control tools which are based on the outcome of commercial/private vehicle simulator and commercial/private vehicle traffic modeling. The present disclosure demonstrates simulated commercial vehicle trip behaviors by, for example, scale of fleet, location throughout terminal, various driving patterns, and across various times and days. The data insights may be used to analyze and build predictive models for commercial vehicle activity and impacts on congestion based on inputs including vehicle behaviors and price sensitivities. The models are then used to direct traffic and provide various travel routes to increase traffic throughout, as predicted by the models.

The subject disclosure works along with or in addition to the subject disclosure shown and described in counterpart U.S. patent application Ser. No. 17/321,333, entitled “GROUND TRANSPORTATION MANAGEMENT,” filed on May 14, 2021, and incorporated herein in its entirety into this disclosure. In brief, the counterpart application describes systems and methods for receiving, processing, and storing commercial vehicle trip data either within a defined geographical location, and/or relating to trip data which starts within, ends within, or includes the defined geographical location during the trip. More specifically, the focus here is airports. Typically, three entities are involved, including (1) a commercial vehicle company system and database (e.g., UBER, LYFT); (2) an airport system and database (e.g., LAX Airport); and (3) a third party system and database, which interacts with and coordinates between the first two systems.

The present subject disclosure describes an end to end system which allows an airport to monitor all commercial vehicles within its defined borders, determine the time period spent by each vehicle within the air port grounds, feed the data into a machine learning system, which then predicts the effects of certain volume and types of vehicles on the airport grounds. The model is then used to direct traffic as needed to increase flow through efficiency on the airport grounds.

I. Operations Management

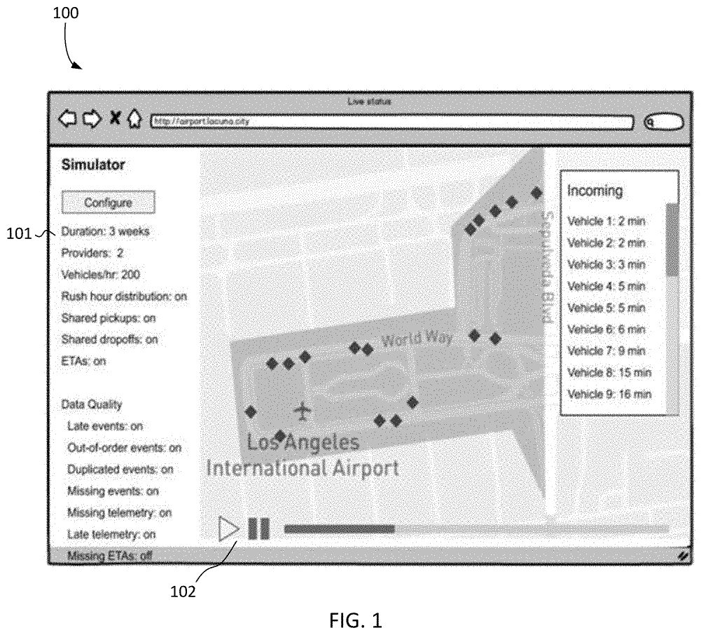

FIG. 1 shows an exemplary view of a simulator interface 100 that includes configurable parameters 101, and play/pause features 102. The simulations of vehicle traffic—passenger car, shuttles, TNCs, buses—allow airport operators to play back data with different volume, time-of-day, and traffic patterns in order to make operations and planning decisions. Different scenarios with different variables are created, and the pattern of traffic is observed in the stimulation, with resulting solutions and the effects of those solutions to the traffic pattern.

Examples of scenarios include but are not limited to: (1) where should traffic be directed under light and heavy traffic loads; what are the consequences of redirecting traffic within airport grounds given certain conditions. (2) If road or lane closures are required for construction or maintenance or security, what are the consequences to traffic and congestion.

As shown in the example of FIG. 1, a three week duration is presented with two commercial providers. A volume of 200 vehicles is used. Shared pickups and drop-offs are also toggled on. The system resiliency is also tested by considering the quality of the data. Various data quality parameters are listed in the simulation. Various identified vehicles and the estimated time of arrival within the configured area is also provided.

II. Automation of Operational Responses in Real-Time Based Simulated Training Data

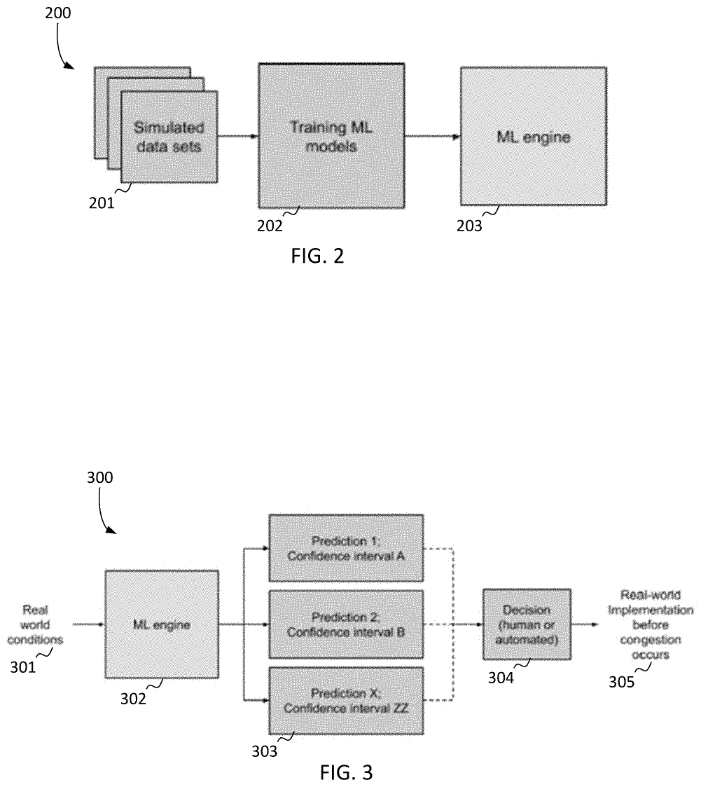

FIGS. 2-3 show that the simulator according to the present subject disclosure can be used to generate a large number of simulated data sets with different parameters and outcomes in the airport environment to feed a machine learning model (the model can be fed with real-world data as well). The model can then be used to help predict outcomes to real-world conditions.

FIG. 2 shows the sequence 200 of providing a simulated data set 201 and providing a solution to the particular data set 202, which solution is then fed into an ML engine 203. For example, for a given volume of commercial vehicles that enter the airport grounds at a specific time interval, certain lanes may be opened to accommodate the increased traffic, which then results in a certain increase in throughput traffic. That solution of certain lanes being open in response to that particular data set is then input into the training ML models, which then is stored into the ML engine. Such solution may be an increase in traffic flow in the newly opened lane, as opposed to the continuously available lane. The subsequent traffic flow, and time in idle and/or transit of vehicles in the area, are fed into the ML engine 203.

FIG. 3 shows a flow chart 300 of how the system can operate to provide a technical solution to a technical problem of determining potential outcomes of traffic when different options are provided. For example, for a given real world condition (certain volume of traffic, certain times of day, etc.) 301, the ML engine is consulted to provide various solutions to ease traffic. The ML engine 302 provides a number of predictions 303, presented as Prediction 1, Prediction 2, and Prediction X. Each Prediction 303 has its own confidence interval, which signifies the degree of statistical confidence that a certain Prediction would occur. Those Predictions are then provided to a decisionmaker 304, which is automated, and/or supplementally controlled by a human. The decisionmaker 304 can then determine which solutions to implement to ease or decrease the traffic volume, including, for example, open up further lanes or service lanes, and/or direct traffic to certain portions of the airport that have less traffic, and close up or limit traffic to the more congested portions of the airport, etc. This may be done automatically by sending electronic instructions to networked motors to activate them to open up gates to certain auxiliary roads, close gates on other roads, put up or pull down road barriers, turn on traffic direction signals to direct traffic a designated way, or even turn on “no stopping” signs in certain sections of the airport. All of these real world physical implementations 305 are designed to prevent congestion, and thereby maintain efficiency, of traffic flow through a given area.

For example, if stopped traffic should surge in one location on the terminal loop, the model can predict (with a confidence interval) the downstream effects. The system can then automatically:
Notify operations staff to prevent a certain number of vehicles from stopping in that location before congestion accumulates.
Notify connected vehicles (via broadcast, push notification, API, etc.) of restricted stopping areas and alternative locations.

III. Using Real World Data to Improve Simulated Data

Real world data reveals the frequency and patterns of certain outcomes, based on current conditions. These conditions can manually or automatically be fed back into the simulator logic.

A non-limiting example includes: an increase of congestion in one location may cause navigation systems (Google Maps, Waze, Apple Maps, Uber routing, OSRM shortest path systems, etc.) to re-route drivers (or autonomous vehicles) along various paths, not necessarily computed by a simulator's routing engine logic. These captured real-world routes can be fed back into the simulator's logic. The input can be represented as a percentage of trips, random variables, etc.

IV. Using Simulated Data to Predict Infrastructure Wear

Roads within the airport are built to last a predicted amount of time. Simulated traffic data can be used to help predict road wear. Using the various vehicle weights multiplied over the number of trips, and accounting for seasonal weather, a simulator could help estimate infrastructure degradation. Infrastructure staff can use this data to better plan for maintenance. For example, to lessen the wear and tear on roads that are more costly to repair or replace, the system may be used to direct traffic through a route which has minimal roads or roads that are less costly to repair or replace, so that there is less long term cost to the airport. Stated simply, the present systems and methods may be used to decrease traffic flow (and thus, wear and tear) on more costly roads, and in turn increase traffic flow (and thus, wear and tear) on less costly roads. This pattern saves the airport money and decreases the time that any of the roads are not in use for repair, which in turn would increase traffic.

V. Testing Platform Systems for Scale and Resiliency

Real world data reveals the frequency and patterns of certain outcomes, based on current conditions. These conditions can manually or automatically be fed back into the simulator logic.

1. Streaming

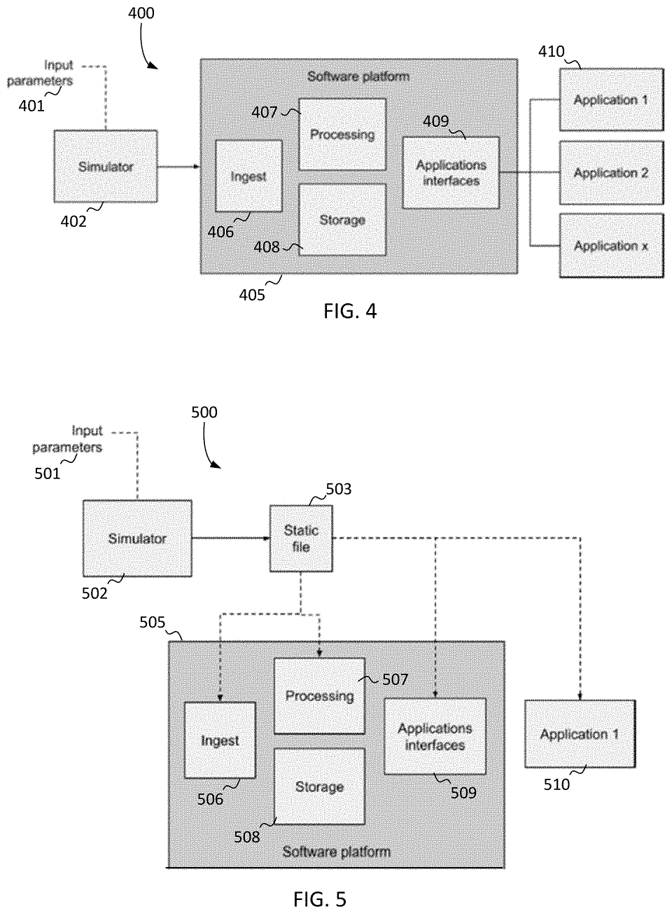

FIG. 4 shows a streaming system 400 with various input parameters 401 feeding into the simulator 402, which connects to the platform 405 via standard MDS connections, and streams vehicle trips and events into the platform 405. The various parts of the platform 405, which incudes, for example, ingest 406, processing 407, storage 408, and applications interfaces 409, can be tested for security, data traffic volume, erroneous data detection, etc., before being surfaced on client applications 410.

2. Static Files

FIG. 5 shows a static system 500 with various input parameters 501 feeding into the simulator 502 can be configured to generate a data set that represents trips that occurred between two points in time. The output is a static file 503 (e.g., CSV or JSON). The static file 503 can be loaded into a database for unit, load, and feature testing of individual software services, including ingest 506, processing 507, storage 508, applications interfaces 509, and client applications 510. In this method, instead of testing the entire system 500, the data can go through individual portions 506, 507, 508, 509, 510 of the system that are responsible for handling data.

In summary, FIG. 4 shows the ability to push real time data through a system 400, and have it all work together to test the system. And FIG. 5 is the ability to feed data into individual parts of the system 500 to test the individual parts.

VI. Simulator Architecture

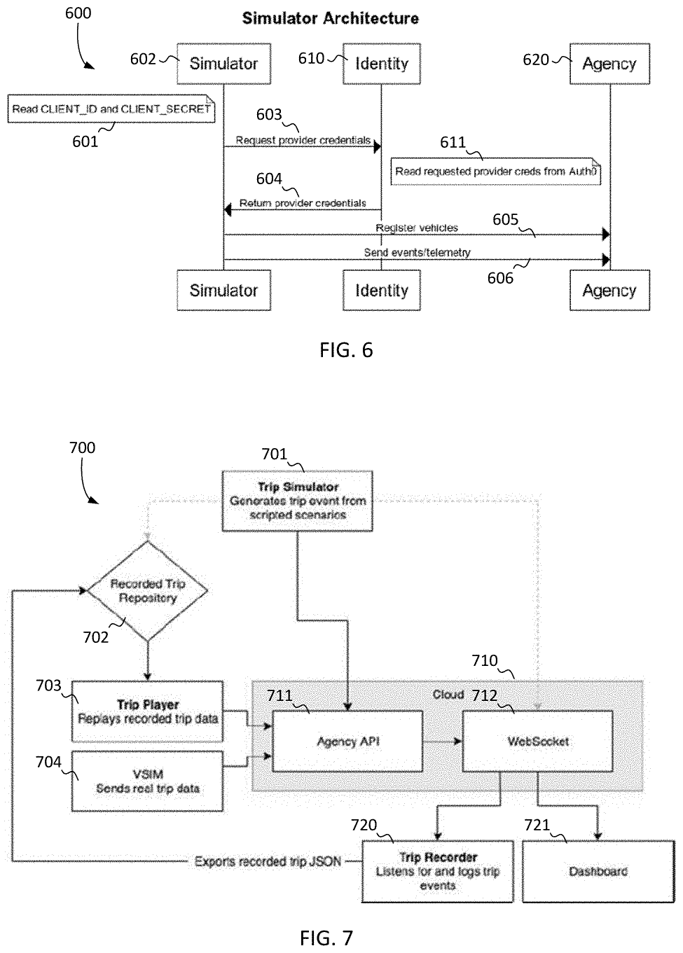

FIG. 6 shows details of an exemplary simulator architecture 600. In this process, the process masquerades as individual providers by pulling API credentials down. A service called IDENTITY is used. The simulator signals that these are the provider's IDs whose tokens are needed. IDENTITY gives back the tokens. Then an agency is called as if the simulator was UBER or LYFT, etc. Thereafter, events/telemetry is provided to the agency.

Viewing the simulator architecture 600 shown in FIG. 6, a client ID 601 is read into the simulator 602, which requests provider credentials 603 from the Identity 610. The Identity 610 then allows the Identity 610 to read requested provider credentials 611 from the Agency 620. Identity 610 then returns provider credentials 604 back to the Simulator 602. This allows Simulator 602 to send register vehicles 605 and send events/telemetry 606 info directly to the Agency 606.

VII. How Simulator Works

FIG. 7 provides a flowchart 700 showing how an exemplary simulator works. A Trip Simulator 701 generates trip events from scripted scenarios. The trip events may be fed into a Recorded Trip Repository 702 and a WebSocket 712 in the Cloud 710. The Agency API 711 is the focal point of the simulation. The Agency API 711 receives input from the Trip Simulator 701, the Trip Player 703, and the VSIM 704 which sends real trip data. The outcomes of the Trip Simulations are played back by the Trip Player 703, and is an array of trip data, and feeds into the Agency API 711. The Trip Recorder 720 listens to the events that the Agency API 711 is receiving via the WebSocket 712. The Trip Recorder 720 then records those events and preserves them in JSON files. They are then plugged into the Trip Player 703. A dashboard 721 provides an outlet to the WebSocket 712.

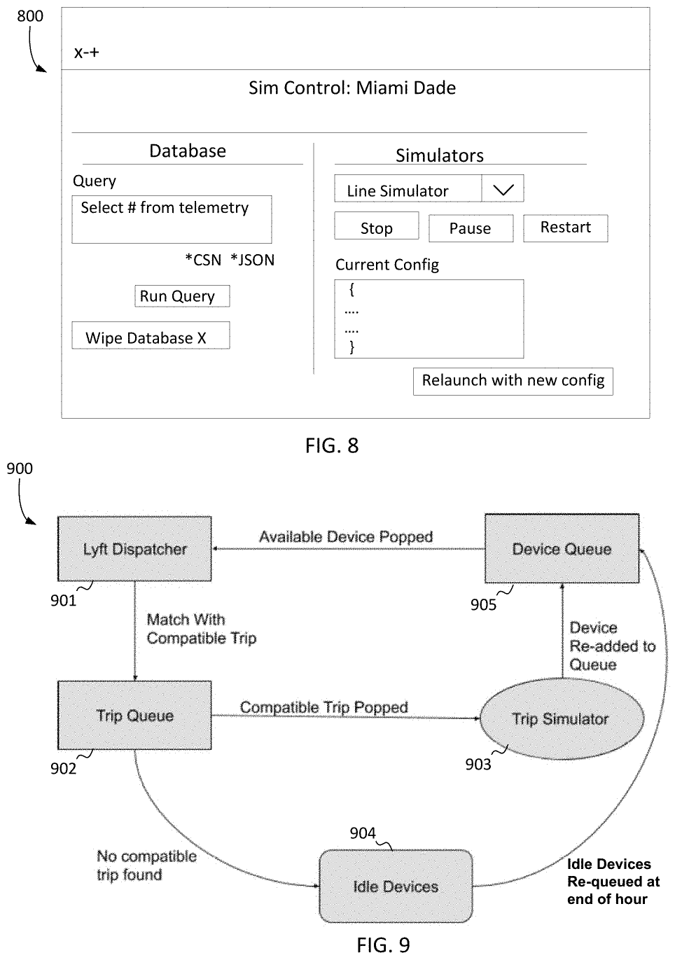

FIG. 8 shows a simulator control of an airport. Shown is an exemplary panel 800 that can control the simulator. Various abilities are shown including start, stop, pause, change parameters, relaunch the simulation, run database queries to pull resulting data out that was generated by the simulations, etc.

FIG. 9 shows a dispatcher loop 900 of how simulation operates “under the hood.” In this example, what is presented is dispatching trips for LYFT. There are two queues, a first queue for devices which are the vehicles, and a second queue for trips for the vehicles to make. This dispatcher algorithm constantly tries to match devices with compatible trips that are trying to be simulated. The constraints around the trips could be their physical locations, or devices that have been idle for a while. There may be several variations. One variation is where there is backfilling data where the algorithm is run for a desired period of time of data (for example, a month of back filled data) and then it's done. Another variation is where the algorithm is run indefinitely in real time mode and where it is continuously generating vehicle trip data.

In the flow chart shown in FIG. 9, a Lyft Dispatcher 901 matches with compatible trip to Trip Queue 902. If a compatible trip is popped, then this leads to Trip Simulator 903, with the device re-added to queue, and leading to a Device Queue 905. The available device is then popped back to the Lyft Dispatcher 901. Alternatively, if the trip Queue 902 results in no compatible trip found, then this indicates an Idle Device 904, which is re-queues at, for example, the end of the hour, back to the Device Queue 905. The available device is then popped back to the Lyft Dispatcher 901. Other configurations are also possible and within the purview of one having ordinary skill in the art after consideration of the present subject disclosure.

The foregoing disclosure of the exemplary embodiments of the present subject disclosure has been presented for purposes of illustration and description. It is not intended to be exhaustive or to limit the subject disclosure to the precise forms disclosed. Many variations and modifications of the embodiments described herein will be apparent to one of ordinary skill in the art in light of the above disclosure. The scope of the subject disclosure is to be defined only by the claims appended hereto, and by their equivalents.

Further, in describing representative embodiments of the present subject disclosure, the specification may have presented the method and/or process of the present subject disclosure as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present subject disclosure should not be limited to the performance of their steps in the order written, and one skilled in the art can readily appreciate that the sequences may be varied and still remain within the spirit and scope of the present subject disclosure.

What is claimed is:

1. A system of managing ground transportation, comprising:
a logic component on a server system which receives traffic information about a plurality of vehicles within a geographically defined area;
a logic component on a server system that provides the traffic information to a machine learning engine, wherein the machine learning engine contains a plurality of traffic pattern simulations;
a logic component on the server system that provides a prediction of the traffic pattern simulation based on the traffic information; and
a logic component on the server system that redirects traffic in response to the prediction based on the traffic information.

2. The system in claim 1, wherein the logic component on the server system that redirects traffic activates a road closing gate.

3. The system in claim 1, wherein the logic component on the server system that redirects traffic activates a road direction signal.

4. The system in claim 1, wherein the logic component on the server system that redirects traffic activates a no stopping light.

5. The system in claim 1, wherein the vehicle is a commercial vehicle.

6. The system in claim 1, wherein the vehicle comprises a dual purpose personal and commercial vehicle.

7. The system in claim 1, wherein the plurality of vehicles belong to different commercial companies.

8. The system in claim 1, wherein the commercially active geographical defined area includes an airport.

9. A system of managing ground transportation, comprising:
a logic component on a server system which receives traffic information about a plurality of commercial vehicles within a geographically defined area;
a logic component on a server system that provides the traffic information to a machine learning engine, wherein the machine learning engine contains a plurality of traffic pattern simulations;
a logic component on the server system that provides a prediction of the traffic pattern simulation based on the traffic information; and
a logic component on the server system that redirects traffic in response to the prediction based on the traffic information;
wherein the traffic information and the prediction are stored into the machine learning engine to be used for future predictions.

10. The system in claim 9, wherein the logic component on the server system that redirects traffic activates a road closing gate.

11. The system in claim 9, wherein the logic component on the server system that redirects traffic activates a road direction signal.

12. The system in claim 9, wherein the logic component on the server system that redirects traffic activates a no stopping light.

13. The system in claim 9, wherein the plurality of vehicles belong to different commercial companies.

14. The system in claim 9, wherein the commercially active geographical defined area includes an airport.

15. A method of managing ground transportation, comprising:
receiving traffic information about a plurality of commercial vehicles within a geographically defined area;
providing the traffic information to a machine learning engine, wherein the machine learning engine contains a plurality of traffic pattern simulations;
providing a prediction of the traffic pattern simulation based on the traffic information; and
redirecting traffic in response to the prediction based on the traffic information.

16. The method in claim 15, wherein the logic component on the server system that redirects traffic activates a road closing gate.

17. The method in claim 15, wherein the logic component on the server system that redirects traffic activates a road direction signal.

18. The method in claim 15, wherein the logic component on the server system that redirects traffic activates a no stopping light.

19. The method in claim 15, wherein the vehicle is a commercial vehicle.

20. The method in claim 19, wherein the commercially active geographical defined area includes an airport.
